(19) United States
(12) Patent Application Publication
(10) Pub. No.: US 2024/0292705 A1
(43) Pub. Date: Aug. 29, 2024

(54) DISPLAY DEVICE AND METHOD OF MANUFACTURING DISPLAY DEVICE

(71) Applicant: Samsung Display Co., LTD., Yongin-si (KR)

(72) Inventors: Hak Bum CHOI, Yongin-si (KR); Jang Il KIM, Yongin-si (KR); Jeong Ki KIM, Yongin-si (KR); Jong Hoon KIM, Yongin-si (KR); Su Jin LEE, Yongin-si (KR)

(73) Assignee: Samsung Display Co., LTD., Yongin-si (KR)

(21) Appl. No.: 18/509,487

(22) Filed: Nov. 15, 2023

(30) Foreign Application Priority Data
Feb. 23, 2023 (KR) 10-2023-0024520

(51) Int. Cl. H10K 59/38; H10K 59/12; H10K 59/122; H10K 59/80

(52) U.S. Cl. CPC H10K 59/38; H10K 59/1201; H10K 59/122; H10K 59/8722; H10K 2102/331

(57) ABSTRACT

A display device includes a first layer disposed on a first base layer, a second layer disposed on a second base layer, and a filling layer disposed between the first layer and the second layer. The first layer includes a light-emitting-element layer including a light emitting element, a bank protruding in a thickness direction of the first base layer, and a color conversion layer which is disposed in an area surrounded by the bank and includes a color conversion part including a quantum dot. The bank is disposed between the first base layer and the filling layer.

### CROSS-REFERENCE TO RELATED APPLICATION(S)

This application claims priority to and benefits of Korean patent application No. 10-2023-0024520 under 35 U.S.C. § 119, filed on Feb. 23, 2023 in the Korean Intellectual Property Office, the entire contents of which are incorporated herein by reference.

### BACKGROUND

### 1. Technical Field

The disclosure generally relates to a display device and a method of manufacturing a display device.

### 2. Description of the Related Art

As demands for high-quality display devices increase, it is desirable to improve the light emission efficiency of display devices. Also, it is desirable to prevent a product defect caused by an impurity.

### SUMMARY

Embodiments provide a display device and a method of manufacturing a display device, which can improve light emission efficiency.

In accordance with an aspect of the disclosure, there is provided a display device that may include a first layer disposed on a first base layer, a second layer disposed on a second base layer, and a filling layer disposed between the first layer and the second layer. The first layer may include a light-emitting-element layer that may include a light emitting element, a bank protruding in a thickness direction of the first base layer, and a color conversion layer which is disposed in an area surrounded by the bank and includes a color conversion part including a quantum dot. The bank may be disposed between the first base layer and the filling layer.

The light emitting element may include a first electrode, a second electrode, and a light emitting layer electrically connected to the first electrode and the second electrode. The light-emitting-element layer may include a first insulating layer which is disposed on the second electrode and includes an inorganic material. No organic layer may be disposed between the first insulating layer and the color conversion layer.

A surface of the first insulating layer may extend to the bank.

The color conversion layer may include a second insulating layer capping the color conversion part. The second layer may include a color filter layer including color filters and a third insulating layer capping the color filters. A surface of the filling layer may be covered by the second insulating layer, and another surface of the filling layer may be covered by the third insulating layer.

The surface of the filling layer may extend to the second insulating layer, and another surface of the filling layer may extend to the third insulating layer.

The color conversion part may include a first color conversion part including a first quantum dot forming a first sub-pixel providing light of a first color and a second color conversion part including a second quantum dot forming a second sub-pixel providing light of a second color.

The bank may include an organic material.

The display device may include a display area and a non-display area. The bank may include a boundary bank disposed throughout the display area and the non-display area.

The boundary bank may cover a side surface of the light-emitting-element layer.

The boundary bank may extend to the first insulating layer.

The first layer may include a pixel circuit layer which includes a pixel circuit and is disposed between the light-emitting-element layer and the first base layer. The pixel circuit layer may include an organic via layer most adjacent to the light-emitting-element layer. The boundary bank may extend to the organic via layer.

The display device may further include a sealing part disposed in the non-display area, the sealing part being disposed along an edge of the display device. The sealing part and the boundary bank may have a same thickness.

The first base layer and the second base layer may be spaced apart from each other by a first distance in the display area, and the first base layer and the second base layer may be spaced apart from each other by a second distance in the non-display area.

The first distance and the second distance may be the same.

In accordance with another aspect of the disclosure, there is provided a display device that may include a pixel circuit layer disposed on a base layer, the pixel circuit layer including a pixel circuit, a light-emitting-element layer disposed on the pixel circuit layer, the light-emitting-element layer including a light emitting element including a first electrode, a second electrode, and a light emitting layer disposed between the first electrode and the second electrode and an insulating layer which is disposed on the light emitting element and includes an inorganic material, and a color conversion layer disposed on the light-emitting-element layer, the color conversion layer including a bank protruding in a thickness direction of the base layer and a color conversion part which is disposed in an area surrounded by the bank and includes a quantum dot. The bank and the insulating layer may extend to each other.

In accordance with still another aspect of the disclosure, there is provided a method of manufacturing a display device. The method may include forming a first layer on a first base layer, forming a second layer on a second base layer, and coupling the first layer and the second layer to each other with a filling layer interposed between the first layer and the second layer. The forming of the first layer may include disposing a light-emitting-element layer including a light emitting element on a first base layer, disposing a bank protruding in a thickness of the first base layer, and disposing a color conversion layer including a color conversion part which is disposed in an area surrounded by the bank and includes a quantum dot.

The light emitting element may include a first electrode, a second electrode, and a light emitting layer electrically connected to the first electrode and the second electrode. The light-emitting-element layer may include a first insulating layer which is disposed on the second electrode and includes an inorganic material. No organic layer may be disposed between the first insulating layer and the color conversion layer.

The forming of the second layer may include forming a color filter layer on the second base layer. The color conversion layer may include a second insulating layer capping the color conversion part. The color filter layer may include color filters and a third insulating layer capping the color filters. A surface of the filling layer may be covered by the second insulating layer, and another surface of the filling layer may be covered by the third insulating layer.

### BRIEF DESCRIPTION OF THE DRAWINGS

FIG. 1 is a schematic plan view illustrating a display device in accordance with an embodiment of the disclosure.

FIG. 2 is a schematic cross-sectional view illustrating a display device in accordance with an embodiment of the disclosure.

FIG. 3 is a schematic cross-sectional view illustrating a display device in accordance with an embodiment of the disclosure.

FIG. 4 is a schematic cross-sectional view illustrating a display device in accordance with an embodiment of the disclosure.

FIG. 5 is a schematic enlarged view of area EA1 shown in FIG. 4.

FIG. 6 is a schematic cross-sectional view illustrating a display device in accordance with an embodiment of the disclosure.

FIG. 7 is a flowchart illustrating a method of manufacturing a display device in accordance with an embodiment of the disclosure.

FIGS. 8 to 10 are schematic cross-sectional views illustrating the method of manufacturing the display device in accordance with an embodiment of the disclosure.

### DETAILED DESCRIPTION OF THE EMBODIMENTS

Example embodiments will now be described more fully hereinafter with reference to the accompanying drawings; however, the disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure.

As used herein, the singular forms are intended to include the plural forms as well, unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Further, an expression that an element such as a layer, region, substrate or plate is placed “on” or “above” another element indicates not only a case where the element is placed “directly on” or “just above” the other element but also a case where a further element is interposed between the element and the other element. An expression that an element such as a layer, region, substrate or plate is placed “beneath” or “below” another element indicates not only a case where the element is placed “directly beneath” or “just below” the other element but also a case where a further element is interposed between the element and the other element.

It will be understood that the terms “connected to” or “coupled to” may include a physical and/or electrical connection or coupling.

The term “overlap” or “cover” mean that a first object may be above or below or to a side of a second object, and vice versa. Additionally, the terms “overlap” and “cover” may include layer, stack, face or facing, extending over, covering, or partly covering or any other suitable term as would be appreciated and understood by those of ordinary skill in the art.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

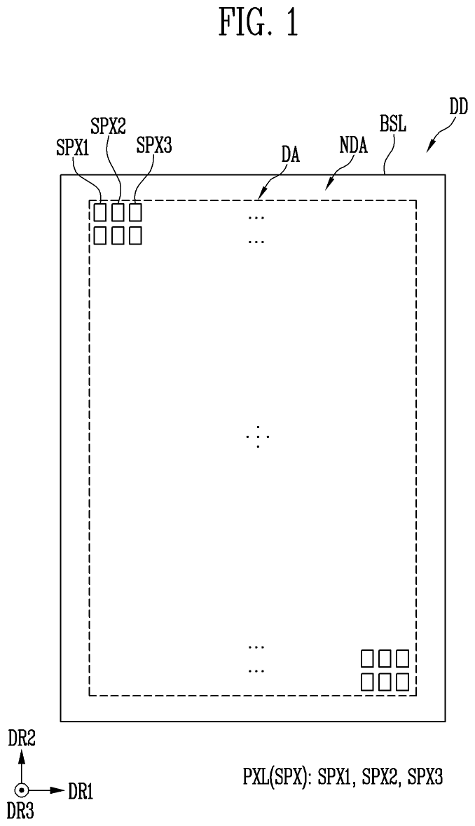

FIG. 1 is a schematic plan view illustrating a display device in accordance with an embodiment of the disclosure.

Referring to FIG. 1, the display device DD may include a base layer BSL and pixels PXL arranged on the base layer BSL. Although not shown in the drawing, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA.

The base layer BSL may form a base surface of the display device DD. The base layer BSL may be a rigid or flexible substrate or film. For example, the base layer BSL may be a rigid substrate made of glass or tempered glass, a flexible substrate (or thin film) made of a plastic or metal material, and/or at least one insulating layer. The material and/or property of the base layer BSL is not particularly limited. In an embodiment, the base layer BSL may be substantially transparent. The term “substantially transparent” may mean that light can be transmitted with a predetermined or selected transmittance or more. In another embodiment, the base layer BSL may be translucent or opaque. In another embodiment, the base layer BSL may include a reflective material.

The base layer BSL may be a first base layer BS1. For example, the first base layer BS1 may form a lower base.

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

In accordance with an embodiment, the pixels PXL (or sub-pixels SPX) may be arranged according to a stripe arrangement structure, a PENTILE™ arrangement structure, or the like. However, the disclosure is not limited thereto, and various embodiments may be applied in the disclosure.

In accordance with an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may constitute one pixel unit capable of emitting lights of various colors.

For example, each of the first sub-pixel SPX1, the second sub-pixel SPX2, and the third sub-pixel SPX3 may emit light of a color. For example, the first sub-pixel SPX1 may be a red pixel emitting light of red (e.g., a first color), the second sub-pixel SPX2 may be a green pixel emitting light of green (e.g., a second color), and the third sub-pixel SPX3 may be a blue pixel emitting light of blue (e.g., a third color). In accordance with an embodiment, a number of second sub-pixels SPX2 may be greater than a number of first sub-pixels SPX1 and a number of third sub-pixels SPX3. However, the color, kind, and/or number of first, second, and third sub-pixels SPX1, SPX2, and SPX3 constituting each pixel unit are not limited to a specific example.

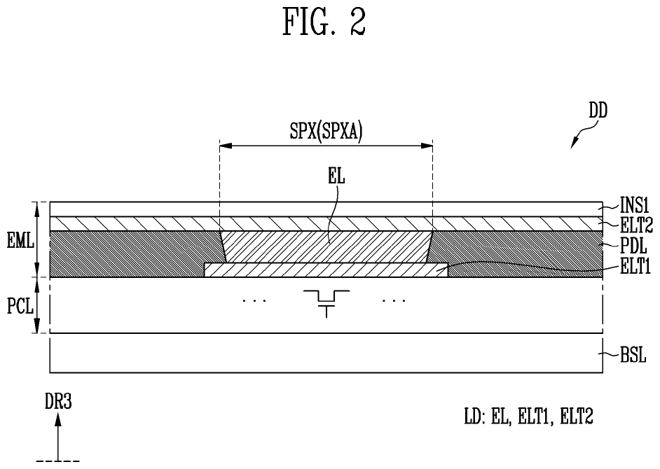

A sectional structure of a display device DD will be described with reference to FIG. 2. FIG. 2 is a schematic cross-sectional view illustrating a display device in accordance with an embodiment of the disclosure.

Referring to FIG. 2, the display device DD may include a base layer BSL, a pixel circuit layer PCL, and a light-emitting-element layer EML.

The base layer BSL may form a base used to allow the pixel circuit layer PCL and the light-emitting-element layer EML to be disposed thereon.

The pixel circuit layer PCL may be disposed on the base layer BSL. The pixel circuit layer PCL may include a pixel circuit for driving light emitting elements LD. The pixel circuit layer PCL may include a display base layer, conductive layers for forming pixel circuits, and insulating layers disposed between the conductive layers.

The pixel circuit may include a thin film transistor. The pixel circuit may include a driving transistor. The pixel circuit may be electrically connected to the light emitting elements LD to provide an electrical signal for allowing the light emitting elements LD to emit light.

The light-emitting-element layer EML may be disposed on the pixel circuit layer PCL. In some embodiments, the light-emitting-element layer EML may include a light emitting element LD, a pixel defining layer PDL, and a first insulating layer INS1.

The light emitting element LD may include an Organic Light Emitting Diode (OLED).

The light emitting element LD may be disposed on the pixel circuit layer PCL. In some embodiments, the light emitting element LD may include a first electrode ELT1, a light emitting layer EL, and a second electrode ELT2. In some embodiments, the light emitting layer EL may be disposed in an area defined by the pixel defining layer PDL. The pixel defining layer PDL may be adjacent to the periphery of the light emitting layer EL. A surface of the light emitting layer EL may be electrically connected to the first electrode ELT1, and another surface of the light emitting element EL may be electrically connected to the second electrode ELT2.

The first electrode ELT1 may be an anode electrode with respect to the light emitting layer EL, and the second electrode ELT2 may be a common electrode (or cathode electrode) with respect to the light emitting element EL. In some embodiments, the first electrode ELT1 and the second electrode ELT2 may include a conductive material. For example, the first electrode ELT1 may include a conductive material having reflexibility, and the second electrode ELT2 may include a transparent conductive material. However, the disclosure is not limited thereto.

The light emitting layer EL may have a multi-layer thin film structure including a light generation layer. The light emitting layer EL may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. The light emitting layer EL may release light, based on an electrical signal provided from the first electrode ELT1 and the second electrode ELT2.

The light emitting layer EL may form a sub-pixel SPX. The light emitting layer EL may form a sub-pixel area SPXA in which light of a color is emitted. In a plan view, an area of the light emitting layer EL and the sub-pixel area SPXA may correspond to each other. For example, each light emitting layer EL may correspond to each sub-pixel area SPXA.

In some embodiments, any organic layer may not be disposed on the second electrode ELT2 of the light emitting element LD. Experimentally, in case that an organic layer having a roughly thick thickness is disposed on the light emitting element LD, light loss may occur in a process in which light provided from the light emitting element LD is emitted to the outside. However, in some embodiments, no organic layer is disposed on the light emitting element LD, but the first insulating layer INS1 including an inorganic material may be disposed on the light emitting element LD. Accordingly, a risk that light loss will occur can be resolved.

The pixel defining layer PDL may be disposed on the pixel circuit layer PCL, to define a position at which the light emitting layer EL is arranged. The pixel defining layer PDL may include an organic material. In some embodiments, the pixel defining layer PDL may include at least one of acrylic resin, epoxy resin, phenolic resin, polyamide resin, and polyimide resin. However, the disclosure is not limited thereto.

The first insulating layer INS1 may be disposed on the second electrode ELT2. The first insulating layer INS1 may include at least one insulating layer covering the light emitting element LD. The first insulating layer INS1 may be a capping layer for the light emitting element LD.

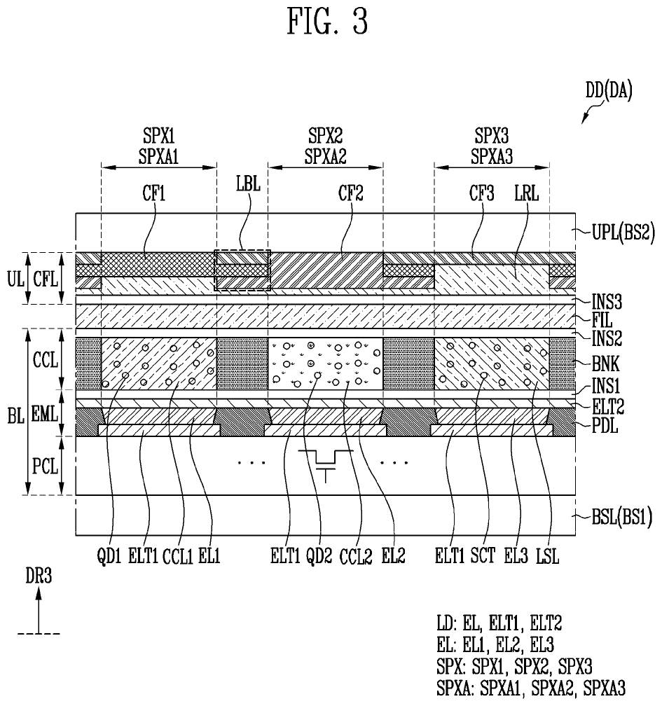

A surface of the first insulating layer INS1 may contact (extend to) a bank BNK (see FIG. 3). Another surface of the first insulating layer INS1 may contact the second electrode ELT2. Accordingly, no organic layer may not be disposed between a color conversion layer CCL (see FIG. 3) and the second electrode ELT2.

In some embodiments, the first insulating layer INS2 may not include an organic material. In some embodiments, the first insulating layer INS1 may include an inorganic material. The inorganic material may include at least one of silicon nitride (SiNₓ), silicon oxide (SiOₓ), silicon oxynitride (SiOₓN_{y}), and aluminum oxide (AlₓO_{y}). However, the disclosure is not limited thereto.

A sectional structure of a display device DD including a color conversion layer CCL in a display area DA in accordance with an embodiment of the disclosure will be described with reference to FIG. 3. In FIG. 3, descriptions of portions overlapping with those described above will be simplified or will not be repeated.

FIG. 3 is a schematic cross-sectional view illustrating a display device in accordance with an embodiment of the disclosure. FIG. 3 illustrates a sectional structure of a display device DD in a display area DA.

Referring to FIG. 3, the display device DD may include a first layer BL, a second layer UL, and a filling layer FIL disposed between the first layer BL and the second layer UL. The first layer BL may be a lower layer of the display device DD. The second layer UL may be an upper layer of the display device DD.

The first layer BL and the second layer UL may be coupled to each other with the filling layer FIL interposed therebetween. For example, after the first layer BL is manufactured, the second layer UL may be manufactured, and the filling layer FIL may be interposed between the first layer BL and the second layer UL, and the first layer BL and the second layer UL may be coupled to each other.

The first layer BL may include a pixel circuit layer PCL, a light-emitting-element layer EML, and a color conversion layer CCL.

A light emitting layer EL forming a light emitting element LD may include a first light emitting layer EL1, a second light emitting layer EL2, and a third light emitting layer EL3.

For example, the display device DD may include sub-pixels SPX1, SPX2, and SPX3 each forming a sub-pixel area SPXA. The sub-pixel areas SPXA may include a first sub-pixel area SPXA1 as an area formed by a first sub-pixel SPX1, in which light of a first color is emitted, a second sub-pixel area SPXA2 as an area formed by a second sub-pixel SPX2, in which light of a second color is emitted, and a third sub-pixel area SPXA3 as an area formed by a third sub-pixel SPX3, in which light of a third color is emitted.

In some embodiments, a light emitting element LD of the first sub-pixel SPX1 may include the first light emitting layer EL1. A light emitting element LD of the second sub-pixel SPX2 may include the second light emitting layer EL2. A light emitting element LD of the third sub-pixel SPX3 may include the third light emitting layer EL3.

In some embodiments, the first to third light emitting layers EL1, EL2, and EL3 may emit light of the third color. However, the disclosure is not necessarily limited thereto.

The color conversion layer CCL may be disposed on the light-emitting-element layer EML. The color conversion layer CCL may include a bank BNK, a first color conversion part CCL1, a second color conversion part CCL2, a light scattering part LSL, and a second insulating layer INS2.

According to the display device DD in accordance with an embodiment of the disclosure, the color conversion parts CCL1 and CCL2 and the light scattering part LSL, which accord with colors of the respective first to third sub-pixels SPX1, SPX2, and SPX3, may be disposed, so that a full-color image can be displayed.

The bank BNK may protrude in a thickness direction of a base layer BSL (e.g., a third direction DR3), and surround an area. For example, the bank BNK may surround an area in which the color conversion parts CCL1 and CCL2 or the light scattering part LSL are disposed. The bank BNK may define an area in which the color conversion parts CCL1 and CCL2 or the light scattering part LSL are disposed.

The bank BNK may be disposed on a first insulating layer INS1. The bank BNK may contact the second insulating layer INS2.

The bank BNK may be patterned during a process of manufacturing the first layer BL using the first base layer BS1 as a base. Accordingly, the bank BNK may be disposed downwardly of the filling layer FIL. For example, the bank BNK may be disposed between the filling layer FIL and the light-emitting-element layer EML.

The bank BNK may include an organic material. For example, the bank BNK may include at least one of acrylic resin, epoxy resin, phenolic resin, polyamide resin, and polyimide resin. However, the disclosure is not limited thereto.

The color conversion parts CCL1 and CCL2 may be configured to change the wavelength of light. The color conversion parts CCL1 and CCL2 and the light scattering part LSL may be disposed downwardly of color filters CF1, CF2, and CF3. The color conversion parts CCL1 and CCL2 and the light scattering part LSL may be disposed between the color filters CF1, CF2, and CF3 and the light-emitting-element layer EML. The color conversion parts CCL1 and CCL2 and the light scattering part LSL may be disposed (or patterned) in an area surrounded by the bank BNK protruding in the thickness direction of the base layer BSL (e.g., the third direction DR3).

The first color conversion part CCL1 may include first color conversion particles for converting light of a third color (e.g., blue) emitted from a blue light emitting layer into light of a first color (e.g., red). For example, the first color conversion part CCL1 may include multiple first quantum dots QD1 dispersed in a predetermined or selected matrix material such as base resin. The first quantum dot QD1 may absorb blue light and emit red light by shifting a wavelength of the blue light according to energy transition.

The second color conversion part CCL2 may include second color conversion particles for converting light of the third color (e.g., blue) emitted from the blue light emitting layer into light of a second color (e.g., green). For example, the second color conversion part CCL2 may include multiple second quantum dots QD2 dispersed in a predetermined or selected matrix material such as base resin. The second quantum dot QD2 may absorb blue light and emit green light by shifting a wavelength of the blue light according to energy transition.

In an embodiment, light of blue having a relatively short wavelength in a visible light band may be incident into the first quantum dot QD1 and the second quantum dot QD2, so that absorption coefficients of the first quantum dot QD1 and the second quantum dot QD2 can be increased. Accordingly, the efficiency of light finally emitted from the first pixel PXL1 and the second pixel PXL2 can be improved, and excellent color reproduction can be ensured.

The light scattering part LSL may be provided to efficiently use light of the third color (e.g., blue) emitted from the blue light emitting layer. For example, the light scattering layer LSL may include a light scattering particle SCT. In an example, the light scattering particle SCT of the light scattering part LSL may include various light scattering particles and various light scattering materials. For example, the light scattering particle SCT may include at least one of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). The light scattering particle SCT may not be disposed in only the third sub-pixel SPX3, and may be selectively comprised in the first color conversion part CCL1 or the second color conversion part CCL2. In some embodiments, the light scattering particle SCT may be omitted such that the light scattering part LSL configured with transparent polymer is provided.

The second insulating layer INS2 may be disposed on the bank BNK, the color conversion parts CCL1 and CCL2, and the light scattering part LSL. The second insulating layer INS2 may be a capping layer for the color conversion layer CCL.

The second insulating layer INS2 may include an inorganic material. The inorganic material may include at least one of silicon nitride (SiNₓ), silicon oxide (SiOₓ), silicon oxynitride (SiOₓN_{y}), and aluminum oxide (AlOₓ). However, the disclosure is not limited thereto.

The filling layer FIL may be disposed between the first layer BL and the second layer UL. For example, the filling layer FIL may be disposed between the color filter layer CFL and a color conversion layer CCL. The filling layer FIL may be disposed between the second insulating layer INS2 and a third insulating layer INS3.

The filling layer FIL may fill a space between the first layer BL and the second layer UL. The filling layer FIL may include a material capable of allowing light to be transmitted therethrough. For example, the filling layer FIL may include a silicon-based organic material, an epoxy-based organic material, and/or an epoxy-acrylic-based organic material. However, the disclosure is not limited thereto, and the filling layer FIL may include various materials.

A surface of the filling layer FIL may be covered by the second insulating layer INS2, and another surface of the filling layer FIL may be covered by the third insulating layer INS3. The surface of the filling layer FIL may contact the second insulating layer INS2, and another surface of the filling layer FIL may contact the third insulating layer INS3.

The second layer UL may include at least one layer disposed on a second base layer BS2. For example, the second layer UL may include the second base layer BS2 and a color filter layer CFL.

The color filter layer CFL may be disposed on the filling layer FIL. The color filter layer CFL may include a first color filter CF1, a second color filter CF2, and a third color filter CF3.

The third insulating layer INS3 may be disposed on the filling layer FIL. The third insulating layer INS3 may be a capping layer for the color filter layer CFL.

The third insulating layer INS3 may include an inorganic material. The inorganic material may include at least one of silicon nitride (SiNₓ), silicon oxide (SiOₓ), silicon oxynitride (SiOₓN_{y}), and aluminum oxide (AlOₓ). However, the disclosure is not limited thereto.

The color filters CF1, CF2, and CF3 may allow light of a color to be selectively transmitted therethrough. In accordance with an embodiment, the color filters CF1, CF2, and CF3 which accord with colors of the respective first to third sub-pixels SPX1, SPX2, and SPX3 are disposed, so that a full-color image can be displayed.

The first color filter CF1 may be a color filter for forming the first sub-pixel SPX1, and may overlap the first sub-pixel area SPXA1 in a plan view. The first color filter CF1 may allow light of a first color to be selectively transmitted therethrough. The first color filter CF1 may be a red color filter, and include a red color filter material.

The second color filter CF2 may be a color filter for forming the second sub-pixel SPX2, and may overlap the second sub-pixel area SPXA2 in a plan view. The second color filter CF2 may allow light of a second color to be selectively transmitted therethrough. The second color filter CF2 may be a green color filter, and include a green color filter material.

The third color filter CF3 may be a color filter for forming the third sub-pixel SPX3, and may overlap the third sub-pixel area SPXA3 in a plan view. The third color filter CF3 may allow light of a third color to be selectively transmitted therethrough. The third color filter CF3 may be a blue color filter, and include a blue color filter material.

In some embodiments, the first to third color filters CF1, CF2, and CF3 may overlap each other in a plan view, and form a light blocking layer LBL. The light blocking layer LBL may be disposed between the sub-pixel areas SPXA. However, the disclosure is not necessarily limited thereto. In some embodiments, a separate light blocking material may be disposed between the sub-pixel areas SPXA to form the light blocking layer LBL.

An upper base layer UPL may be disposed on the color filter layer CFL. The upper base layer UPL may form a base for patterning at least one layer in case that the second layer UL is manufactured.

The upper base layer UPL may be the second base layer BS2. For example, the second base layer BS2 may form an upper base.

The upper base layer UPL may include at least one of the materials described above with reference to the base layer BSL. The upper base layer UPL may include the same material as the base layer BSL. However, the disclosure is not limited thereto, and the upper base layer UPL may include a material different from the material of the base layer BSL.

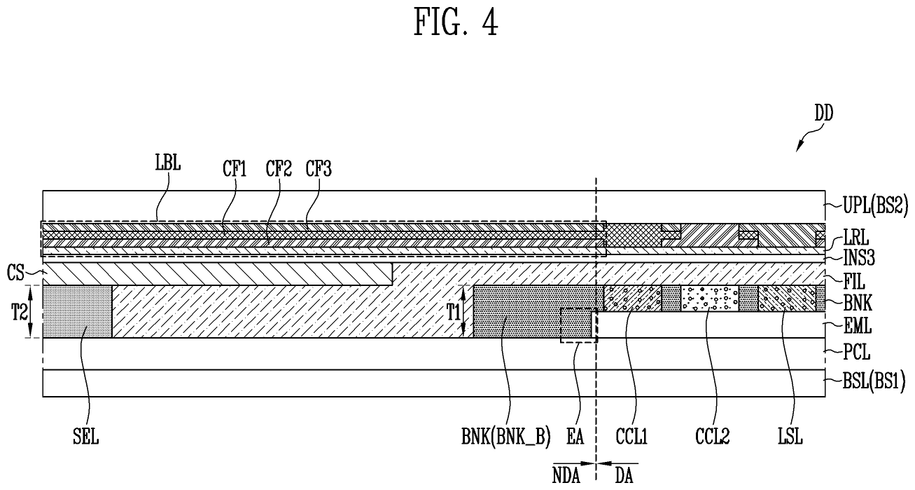

Next, a sectional structure of a display device DD including a color conversion layer CCL in an area in which a display area DA and a non-display area NDA are adjacent to each other in accordance with an embodiment of the disclosure will be described with reference to FIGS. 4 to 6. In FIGS. 4 to 6, descriptions of portions overlapping with those described above will be simplified or will not be repeated.

FIG. 4 is a schematic cross-sectional view illustrating a display device in accordance with an embodiment of the disclosure. FIG. 4 illustrates a sectional structure of a display device DD in an area in which a display area DA and a non-display area NDA are adjacent to each other.

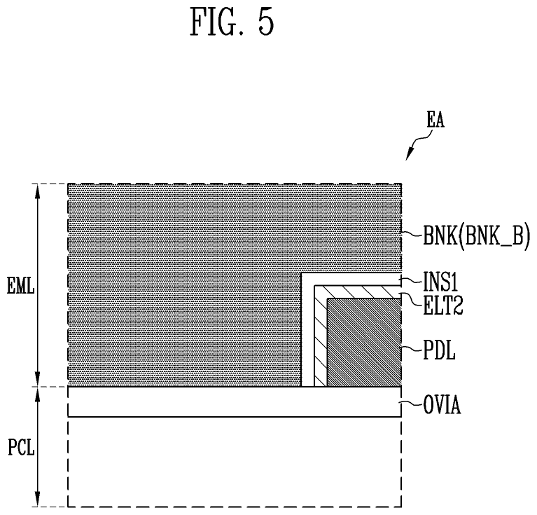

FIG. 5 is a schematic enlarged view of area EA1 shown in FIG. 4. FIG. 5 illustrates a structure in which a bank BNK is disposed in the area in which the display area DA and the non-display area NDA are adjacent to each other.

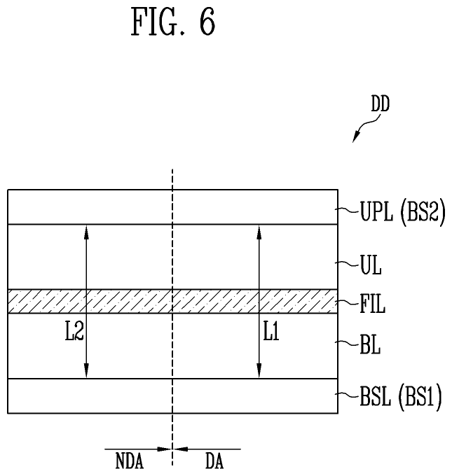

FIG. 6 is a schematic cross-sectional view illustrating a display device in accordance with an embodiment of the disclosure. FIG. 6 illustrates a separation relationship between a first base layer BS1 and a second base layer BS2 in the area in which the display area DA and the non-display area NDA are adjacent to each other, which is shown in FIG. 4.

Referring to FIGS. 4 to 6, a first layer BL, a second layer UL, and a filling layer BIL may be disposed throughout the display area DA and the non-display area NDA.

In some embodiments, the filling layer FIL may fill a gap between the first layer BL and the second layer UL, and accordingly, a separation distance between a first base layer BS1 forming the first layer BL and a second base layer BS2 forming the second layer UL may be roughly uniformly defined. For example, in the display area DA, the first layer BL and the second layer UL may be spaced apart from each other by a first distance L1. In the non-display area NDA, the first layer BL and the second layer UL may be spaced apart from each other by a second distance L2. The first distance L1 and the second distance L2 may be the same.

Experimentally, in case that the gap between the first layer BL and the second layer UL is not uniform, a restoring force of the first base layer BS1 and the second base layer BS2 may be continuously generated at a position at which a relatively narrow gap is formed. However, in some embodiments, the filling layer FIL may roughly uniformly maintain the gap between the first layer BL and the second layer UL, and accordingly, occurrence of stress in the display device DD can be reduced.

In some embodiments, a bank BNK may include a boundary bank BNK_B. The boundary bank BNK_B may be a portion of the bank BNK, and may be disposed throughout the display area DA and the non-display area NDA.

The boundary bank BNK_B may overlap the display area DA in plan view. The boundary bank BNK_B may overlap the non-display area NDA in a plan view.

The boundary bank BNK_B may cover a side surface of a light-emitting-element layer EML. The boundary bank BNK_B may contact a portion of the light-emitting-element layer EML, which is adjacent to (e.g., directly adjacent to) the non-display area NDA. For example, no light emitting layer EL may be disposed in an edge area of the display area DA, which is adjacent to the non-display area NDA, but a pixel defining layer PDL, a second electrode ELT2, and a first insulating layer INS1 may be disposed in the edge area of the display area DA.

The boundary bank BNK_B may be disposed on the pixel defining layer PDL, the second electrode ELT2, and the first insulating layer INS1, which are disposed in the edge region of the display area DA. For example, the boundary bank BNK_B may contact the first insulating layer INS1 disposed in the edge region of the display area DA.

The boundary bank BNK_B may cover a surface of a pixel circuit layer PCL. For example, the boundary bank BNK_B may contact an uppermost layer of the pixel circuit layer PCL. The uppermost layer of the pixel circuit layer PCL may be an organic planarization layer OVIA (e.g., a via layer) which covers pixel circuit elements of the pixel circuit layer PCL, thereby planarizing the pixel circuit layer PCL.

As described above, the bank BNK may be comprised in the first layer BL (e.g., may be disposed on a bottom plate), and no organic layer may be disposed between a color conversion layer CCL and the second electrode ELT2. Accordingly, any excessive step difference according to disposition of an organic layer does not occur. As a result, a gap between the first base layer BS1 and the second base layer BS2 can be roughly uniformly defined in the display area DA and the non-display area NDA, and a risk that a restoring force of the first base layer BS1 and the second base layer BS2 is generated in the non-display area NDA can be reduced.

In case that the restoring force of the first base layer BS1 and the second base layer BS2 is generated, at least a portion of each layer may be damaged. For example, a color filter layer CFL may be damaged, or moisture or the like may infiltrate into a gap occurring as layers are damaged.

However, in some embodiments, as no organic layer may be disposed between the color conversion layer CCL and the second electrode ELT2, occurrence of a step difference may be minimized. Thus, the restoring force of the first base layer BS1 and the second base layer BS2 is not substantially generated, and a risk that the layers will be damaged can be resolved. The bank BNK for forming the color conversion layer CCL covers the light-emitting-element layer EML and the pixel circuit layer PCL, thereby effectively protecting the light-emitting-element layer EML and the pixel circuit layer PCL.

First to third color filters CF1, CF2, and CF3 may overlap each other in the non-display area NDA in a plan view, and form a light blocking layer LBL. Accordingly, lower components in the non-display area NDA may not be viewed from the outside.

The display area DD may further include a sealing part SEL and a moisture prevention layer CS.

The sealing part SEL may be disposed along an outer edge of the display device DD. For example, the sealing part SEL may surround the non-display area NDA and the display area DA. The sealing part SEL may include a material obtained by curing a sealant. For example, the sealant may include a UV cured material or a thermo-setting material. In some embodiments, the sealant may include at least one of a silicon-based resin, an epoxy-based resin, an acrylic-based resin, and a polyimide-based resin. However, the disclosure is not necessarily limited thereto.

In some embodiments, the sealing part SEL and the boundary bank BNK_B may have substantially a same thickness. For example, the boundary bank BNK_B may have a first thickness T1, and the sealing part SEL may have a second thickness T2. The first thickness T1 and the second thickness T2 may be the same. Accordingly, the gap between the first base layer BS1 and the second base layer BS2 can be uniformly provided in the display area DA and the non-display area NDA.

The moisture prevention layer CS may be disposed on the light blocking layer LBL. For example, the moisture prevention layer CS may be disposed along the outer edge of the display device DD. The moisture prevention layer CS may prevent an impurity such as moisture from infiltrating into the display device DD. In some embodiments, the moisture prevention layer CS may include a metal material, but the disclosure is not particularly limited.

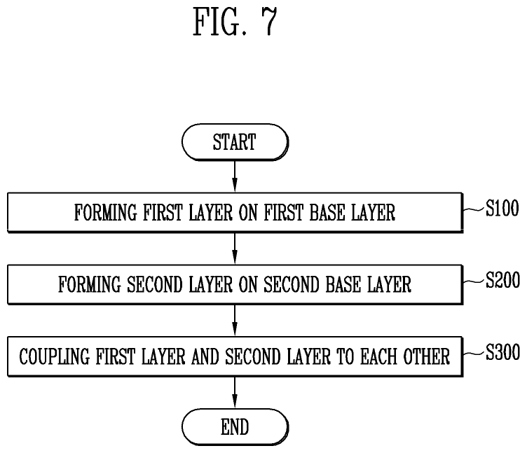

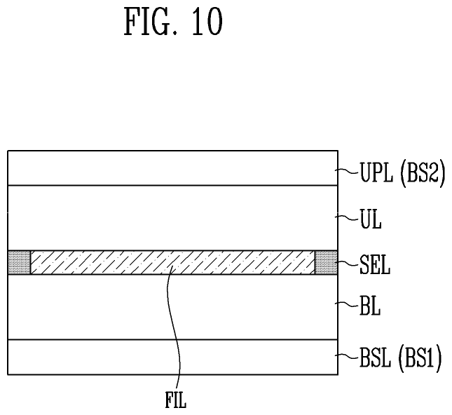

A method of manufacturing a display device DD in accordance with an embodiment of the disclosure will be described with reference to FIGS. 7 to 10. In FIGS. 7 to 10, descriptions of portions overlapping with those described above will be simplified or will not be repeated.

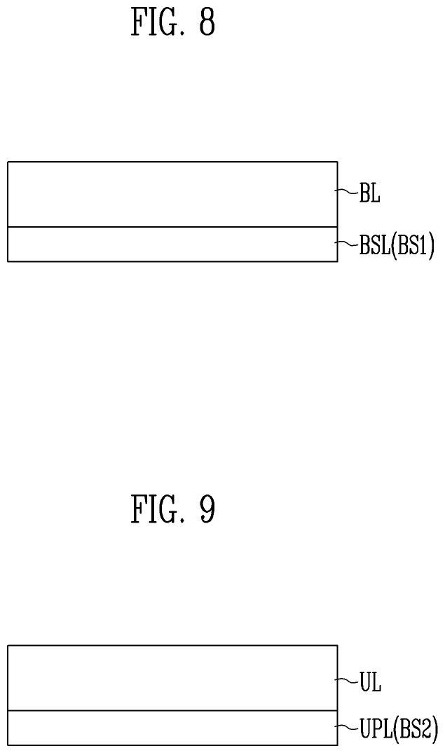

FIG. 7 is a flowchart illustrating a method of manufacturing a display device in accordance with an embodiment of the disclosure. FIGS. 8 to 10 are schematic cross-sectional views illustrating the method of manufacturing the display device in accordance with an embodiment of the disclosure.

Referring to FIG. 7, the method of manufacturing the display device DD may include step S100 of forming a first layer on a first base layer, step S200 of forming a second layer on a second base layer, and step S300 of coupling the first layer and the second layer to each other.

Referring to FIGS. 7 and 8, in the step S100 of forming the first layer on the first base layer, a first base layer BS1 may be prepared, and a first layer BL may be disposed on the first base layer BS1.

In this step, materials for forming a pixel circuit layer PCL, a light-emitting-element layer EML, and a color conversion layer CCL may be patterned on the first base layer BS1.

In this specification, conductive layers and insulating layers may be formed through a patterning process (e.g., a photolithography process or the like) using a mask.

In this step, in case that the light-emitting-element layer EML is disposed, a first insulating layer INS1 may be formed without depositing an organic layer, after a second electrode ELT2 is patterned. A bank BNK may be patterned after the first insulating layer INS1 is formed. The bank BNK may include an organic material, and be patterned to cover the pixel circuit layer PCL and the light-emitting-element layer EML. After the bank BNK is patterned, color conversion parts CCL1 and CCL2 and a light scattering part LSL may be patterned.

Referring to FIGS. 7 and 9, in the step S200 of forming the second layer on the second base layer, a second base layer BS2 may be prepared, and a second layer UL may be disposed on the second base layer BS2.

In this step, materials for forming a color filter layer CFL may be patterned on the second base layer BS2. For example, the at least one layer described above with reference to FIG. 3 may be disposed on the second base layer BS2.

Referring to FIGS. 7 to 10, in the step S300 of coupling the first layer and the second layer to each other, the first layer BL and the second layer UL may be coupled to each other with a filling layer FIL interposed therebetween.

In this step, the filling layer FIL may be interposed between the first layer BL and the second layer UL, and a sealing part SEL may be disposed along an outer area of the filling layer FIL. The filling layer FIL may be vacuum-compressed such that the first layer BL and the second layer UL are adjacent to each other. Accordingly, as the filling layer FIL may be compressed, the filling layer FIL may be disposed to be spread throughout a display area DA and a non-display area NDA. The sealing part SEL may restrict an area in which the filling layer FIL is disposed, and seal other components. For example, the sealing part SEL may be manufactured by disposing a sealant along an edge of the display device DD and curing the sealant. Accordingly, a display device in accordance with an embodiment of the disclosure can be manufactured.

In some embodiments, the first layer BL and the second layer UL may be coupled to each other after the bank BNK is disposed on the first base layer BS1 without disposing an organic layer having an excessive thickness. Accordingly, a gap between the first base layer BS1 and the second base layer BS2 can be uniformly provided. Thus, as described above, a risk which may occur as the gap between the first base layer BS1 and the second base layer BS2 is non-uniform can be reduced.

In accordance with the disclosure, there can be provided a display device and a method of manufacturing a display device, which can improve light emission efficiency.

In accordance with the disclosure, there can be provided a display device and a method of manufacturing a display device, which can reduce a risk that a defect will occur in a product structure.

Example embodiments have been disclosed herein, and although specific terms are employed, they are used and are to be interpreted in a generic and descriptive sense only and not for the purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A display device, comprising:
a first layer disposed on a first base layer;
a second layer disposed on a second base layer; and
a filling layer disposed between the first layer and the second layer, wherein
the first layer comprises:
a light-emitting-element layer comprising a light emitting element;
a bank protruding in a thickness direction of the first base layer; and
a color conversion layer which is disposed in an area surrounded by the bank and comprises a color conversion part comprising a quantum dot, and
the bank is disposed between the first base layer and the filling layer.

2. The display device of claim 1, wherein
the light emitting element comprises:
a first electrode;
a second electrode; and
a light emitting layer electrically connected to the first electrode and the second electrode,
the light-emitting-element layer comprises a first insulating layer which is disposed on the second electrode and comprises an inorganic material, and
no organic layer is disposed between the first insulating layer and the color conversion layer.

3. The display device of claim 2, wherein a surface of the first insulating layer extends to the bank.

4. The display device of claim 1, wherein
the color conversion layer comprises a second insulating layer capping the color conversion part,
the second layer comprises a color filter layer comprising color filters and a third insulating layer capping the color filters,
a surface of the filling layer is covered by the second insulating layer, and
another surface of the filling layer is covered by the third insulating layer.

5. The display device of claim 4, wherein
the surface of the filling layer extends to the second insulating layer, and
another surface of the filling layer extends to the third insulating layer.

6. The display device of claim 1, wherein the color conversion part comprises a first color conversion part comprising a first quantum dot forming a first sub-pixel providing light of a first color and a second color conversion part comprising a second quantum dot forming a second sub-pixel providing light of a second color.

7. The display device of claim 1, wherein the bank comprises an organic material.

8. The display device of claim 2, comprising a display area and a non-display area,
wherein the bank comprises a boundary bank disposed throughout the display area and the non-display area.

9. The display device of claim 8, wherein the boundary bank covers a side surface of the light-emitting-element layer.

10. The display device of claim 9, wherein the boundary bank extends to the first insulating layer.

11. The display device of claim 9, wherein
the first layer comprises a pixel circuit layer which comprises a pixel circuit and is disposed between the light-emitting-element layer and the first base layer,
the pixel circuit layer comprises an organic via layer most adjacent to the light-emitting-element layer, and
the boundary bank extends to the organic via layer.

12. The display device of claim 8, further comprising:
a sealing part disposed in the non-display area, the sealing part being disposed along an edge of the display device,
wherein the sealing part and the boundary bank have a same thickness.

13. The display device of claim 8, wherein
the first base layer and the second base layer are spaced apart from each other by a first distance in the display area, and
the first base layer and the second base layer are spaced apart from each other by a second distance in the non-display area.

14. The display device of claim 13, wherein the first distance and the second distance are the same.

15. A display device, comprising:
a pixel circuit layer disposed on a base layer, the pixel circuit layer comprising a pixel circuit;
a light-emitting-element layer disposed on the pixel circuit layer, the light-emitting-element layer comprising:
a light emitting element comprising:
a first electrode;
a second electrode; and
a light emitting layer disposed between the first electrode and the second electrode; and
an insulating layer which is disposed on the light emitting element and comprises an inorganic material; and
a color conversion layer disposed on the light-emitting-element layer, the color conversion layer comprising:
a bank protruding in a thickness direction of the base layer; and
a color conversion part which is disposed in an area surrounded by the bank and comprises a quantum dot,
wherein the bank and the insulating layer extend to each other.

16. A method of manufacturing a display device, the method comprising:
forming a first layer on a first base layer;
forming a second layer on a second base layer; and
coupling the first layer and the second layer to each other with a filling layer interposed between the first layer and the second layer,
wherein the forming of the first layer comprises:
disposing a light-emitting-element layer comprising a light emitting element on a first base layer;
disposing a bank protruding in a thickness of the first base layer; and
disposing a color conversion layer comprising a color conversion part which is disposed in an area surrounded by the bank and comprises a quantum dot.

17. The method of claim 16, wherein
the light emitting element comprises:
a first electrode;
a second electrode; and
a light emitting layer electrically connected to the first electrode and the second electrode,
the light-emitting-element layer comprises a first insulating layer which is disposed on the second electrode and comprises an inorganic material, and
no organic layer is disposed between the first insulating layer and the color conversion layer.

18. The method of claim 17, wherein
the forming of the second layer comprises forming a color filter layer on the second base layer,
the color conversion layer comprises a second insulating layer capping the color conversion part,
the color filter layer comprises color filters and a third insulating layer capping the color filters,
a surface of the filling layer is covered by the second insulating layer, and
another surface of the filling layer is covered by the third insulating layer.
